(19) United States
(12) Patent Application Publication
(10) Pub. No.: US 2026/0371797 A1
(43) Pub. Date: Nov. 19, 2026

(54) LIGHTING SYSTEMS AND ASSOCIATED METHODS OF COMBINING VISIBLE AND NON-VISIBLE LIGHT CONVERTING PHOSPHOR

(71) Applicant: Dominant Opto Technologies Sdn Bhd., Melaka (MY)

(72) Inventors: TEK BENG LOW, MELAKA (MY); ENG WAH TAN, MELAKA (MY); CHEE SHENG LIM, MELAKA (MY)

(21) Appl. No.: 19/741,627

(22) Filed: Jul. 14, 2026

Related U.S. Application Data
(63) Continuation-in-part of application No. 18/404,505, filed on Jan. 4, 2024, now Pat. No. 12,701,832.
Application No. 18/404,505 is a continuation-in-part of application No. 17/891,965, filed on Aug. 19, 2022, now abandoned.
Application No. 17/891,965 is a division of application No. 16/541,584, filed on Aug. 15, 2019, now abandoned.
Application No. 16/541,584 is a continuation-in-part of application No. 15/797,843, filed on Oct. 30, 2017, now abandoned.

(30) Foreign Application Priority Data
Oct. 25, 2017 (MY) PI2017704026

(51) Int. Cl. H10H 20/851

(52) U.S. Cl. CPC H10H 20/8512

(57) ABSTRACT

Lighting systems and associated methods of combining visible and non-visible light converting phosphor are presented herein. A method comprises varying respective amounts of a non-visible light converting phosphor and respective amounts of a visible light converting phosphor that are included in respective encapsulants that have been used to encapsulate LED chips of respective samples of a group of LED chips within respective LED test packages; based on determined mathematical relationships and correlations associated with the varying, including a first amount of the non-visible light converting phosphor and a second amount of the visible light converting phosphor in an encapsulant; and encapsulating, using the encapsulant, a manufacturing portion of the group of LED chips within respective LED packages to facilitate categorization of the respective LED packages into a manufacturing bin represented by a defined target LED package light output intensity and a defined target LED package light output color coordinate.

### CROSS-REFERENCE TO RELATED APPLICATIONS

The subject patent application is a continuation-in-part of, and claims priority to, U.S. patent application Ser. No. 18/404,505, filed on Jan. 4, 2024, and entitled “LIGHTING SYSTEMS AND ASSOCIATED METHODS OF COMBINING VISIBLE AND NON-VISIBLE LIGHT CONVERTING PHOSPHOR”, which is a continuation-in-part of, and claims priority to, U.S. patent application Ser. No. 17/891,965, filed on Aug. 19, 2022, and entitled “LIGHTING SYSTEMS AND ASSOCIATED METHODS COMBINING VISIBLE AND NON-VISIBLE LIGHT CONVERTING PHOSPHOR”, which is a divisional of, and claims priority to, U.S. patent application Ser. No. 16/541,584, filed Aug. 15, 2019, and entitled “LIGHTING SYSTEMS AND ASSOCIATED METHODS COMBINING VISIBLE AND NON-VISIBLE LIGHT CONVERTING PHOSPHOR”, which is a continuation-in-part of, and claims priority to, U.S. patent application Ser. No. 15/797,843, filed Oct. 30, 2017, and entitled “LIGHTING SYSTEMS AND METHODS COMBINING VISIBLE AND NON-VISIBLE LIGHT CONVERTING PHOSPHOR”, which claims priority to Malaysian Patent Application Serial No. Pl2017704026, filed Oct. 25, 2017, the entirety of which applications are hereby incorporated by reference herein.

### TECHNICAL FIELD

The subject disclosure generally relates to embodiments for lighting systems and associated methods of combining visible and non-visible light converting phosphor.

### BACKGROUND

Generally, light emitting diodes (LEDs) are used in a broad range of industrial applications, primarily due to multiple advantages of LEDs including, but not limited to, energy efficiency, low power consumption, small size, durability, long life, low heat generation, and the like.

During manufacturing and production of LEDs, LED manufacturers focus a majority of their efforts on the testing and quality control of LEDs. Consequently, it is common to sort the LEDs as per different criteria, e.g., light output color (wavelength), light output brightness or intensity (lumen output), forward voltage, and the like. This process of sorting LEDs is generally known as binning, e.g., partitioning the LEDs into groups of different output colors and intensities. The criterion of binning is commonly known as binning parameters.

A main goal of LED manufacturers is to make the binning process more efficient. In most applications, multiple LEDs are used and placed side-by-side, e.g., in a display panel. Accordingly, it is important that LEDs from the same bin, e.g., corresponding to a similar light output color and intensity, are utilized to ensure uniformity in the display panel; otherwise, LEDs that are selected from different bins corresponding to different light output colors and intensities and that are placed side-by-side in a display panel will result in a non-uniform appearance of the display panel.

A challenge facing conventional LED manufacturers is not being able to reduce a number of bins during the production of LEDs-due to variations in the production of LED chips, it is not possible to produce sufficiently similar LEDs in high volume.

### BRIEF DESCRIPTION OF THE DRAWINGS

Non-limiting embodiments of the subject disclosure are described with reference to the following Figures, in which like reference numerals refer to like parts throughout the various views unless otherwise specified:

FIG. 1 illustrates a block diagram of a lighting system comprising an LED package that comprises an LED chip that has been encapsulated with a phosphor material comprising visible and non-visible light converting phosphor, in accordance with various example embodiment(s);

FIG. 2 illustrates a block diagram of respective lighting systems comprising LED packages that comprise respective LED chips that have been encapsulated with respective phosphor materials, in accordance with various example embodiment(s).

FIG. 3 illustrates a block diagram of bins of LED chips comprising respective light output intensities and respective light output wavelengths, in accordance with various example embodiment(s);

FIG. 4 illustrates a block diagram associated with process(es) for manufacturing LED packages comprising respective LED chips that have been encapsulated with respective phosphor materials comprising visible and non-visible light converting phosphor, in accordance with various example embodiment(s);

FIG. 5 illustrates a block diagram of a table displaying mathematical relationships between different weight percentages of a non-visible light converting phosphor material that have been added to respective encapsulants used to encapsulate respective LED chips within respective LED test packages, changes in light output intensity of the LED test packages from a defined 100% light output intensity of such packages, and changes in light output wavelength of the LED test packages from a light output wavelength corresponding to the defined 100% LED light output intensity, in accordance with various example embodiment(s);

FIG. 6 illustrates a block diagram of an International Commission on Illumination (“CIE”) color space chromaticity diagram (illustrated in greyscale) associated with process(es) for manufacturing LED packages comprising respective LED chips that have been encapsulated with respective phosphor materials comprising visible and non-visible light converting phosphor, in accordance with various example embodiment(s);

FIG. 7 illustrates another block diagram associated with process(es) for manufacturing LED packages comprising respective LED chips that have been encapsulated with respective phosphor materials comprising visible and non-visible light converting phosphor, in accordance with various example embodiment(s);

FIGS. 8-9 illustrate flow charts of a method associated with process(es) for manufacturing LED packages comprising respective LED chips that have been encapsulated with respective phosphor materials comprising visible and non-visible light converting phosphor, in accordance with various example embodiment(s); and

FIG. 10 illustrates a flow chart of another method associated with process(es) for manufacturing LED packages comprising respective LED chips that have been encapsulated with respective phosphor materials comprising visible and non-visible light converting phosphor, in accordance with various example embodiment(s);

FIG. 11 illustrates a flow chart of yet another method associated with process(es) for manufacturing LED packages comprising respective LED chips that have been encapsulated with respective phosphor materials comprising visible and non-visible light converting phosphor, in accordance with various example embodiment(s); and

FIG. 12 illustrates a plot of normalized intensity per light output wavelength of electromagnetic radiation that has been emitted/output by an LED package, in which the LED package comprises an LED chip that has been encapsulated with an encapsulant comprising a phosphor material comprising visible light converting phosphor and non-visible light converting phosphor, in accordance with various example embodiment(s).

### DETAILED DESCRIPTION

Aspects of the subject disclosure will now be described more fully hereinafter with reference to the accompanying drawings in which example embodiments are shown. In the following description, for purposes of explanation, numerous specific details are set forth in order to provide a thorough understanding of the various embodiments. However, the subject disclosure may be embodied in many different forms and should not be construed as limited to the example embodiments set forth herein.

As described above, conventional LED manufacturers are not able to reduce a number of bins during the production of LEDs due to variations in production of LED chips. In various embodiment(s) described herein, respective LED packages and method(s)/process(es) for manufacturing the respective LED packages utilize a combination of visible and non-visible light converting phosphor to encapsulate LED chips within respective LED packages to limit a number of bins of such packages during production-the visible light converting phosphor converting visible light from one wavelength/light output to another visible light of a different wavelength/light output, and the non-visible light converting phosphor converting visible light to non-visible wavelengths like infrared or ultraviolet, e.g., a non-visible light range, e.g., to control a brightness and/or intensity of the visible light.

In this regard, in embodiment(s), an LED package comprises an LED chip that has been encapsulated with an encapsulant that comprises a first defined quantity of a visible light converting phosphor and a second defined quantity of a non-visible light converting phosphor, in which the LED package outputs, based on the first defined quantity of the visible light converting phosphor and the second defined quantity of the non-visible light converting phosphor, an LED package light output comprising a defined LED package light output color coordinate and a defined LED package light output intensity, in which the visible light converting phosphor emits first electromagnetic radiation in a visible light spectrum, and in which the non-visible light converting phosphor emits second electromagnetic radiation in a non-visible light spectrum.

Further, the LED package comprises respective lead frames that are electrically connected, via wires, to electrical pads of the LED chip, in which the respective lead frames facilitate bonding of the LED package to a printed circuit board.

In other embodiment(s), the LED chip has been determined to generate an LED chip light output comprising a color that is within a defined LED chip light output color range; and the defined LED package light output color coordinate is based on the color of the LED chip light output that is within the defined LED chip light output color range.

In yet other embodiment(s), the defined LED package light output color coordinate is further based on the first defined quantity of the visible light converting phosphor that has been included in the encapsulant.

In embodiment(s), the first defined quantity of the visible light converting phosphor comprises a defined weight percentage of the visible light converting phosphor with respect to a weight of the encapsulant comprising the first defined quantity of the visible light converting phosphor and the second defined quantity of the non-visible light converting phosphor.

In other embodiment(s), the LED chip has been determined to generate an LED chip light output comprising an intensity that is within a defined LED chip light output intensity range; and the defined LED package light output intensity is based on the intensity of the LED chip light output that is within the defined LED chip light output intensity range.

In yet other embodiment(s), the defined LED package light output intensity is further based on the second defined quantity of the non-visible light converting phosphor that has been included in the encapsulant.

In embodiment(s), the defined LED package light output intensity is negatively proportional to the second defined quantity of the non-visible light converting phosphor that has been included in the encapsulant.

In other embodiment(s), the second defined quantity of the non-visible light converting phosphor comprises a defined weight percentage of the non-visible light converting phosphor with respect to a weight of the encapsulant comprising the first defined quantity of the visible light converting phosphor and the second defined quantity of the non-visible light converting phosphor.

In yet other embodiment(s), the defined LED package light output intensity comprises a defined target light output brightness for white light.

In embodiment(s), the defined LED package light output color coordinate comprises an output color coordinate of a defined color space.

In other embodiment(s), the LED chip comprises a blue LED chip or an ultraviolet LED chip.

In yet other embodiment(s), a portion of electromagnetic radiation that is output/emitted (e.g., as an LED package output) by the LED package via the visible light converting phosphor, e.g., corresponding to a presence of the visible light converting phosphor in an encapsulant of the LED package, comprises a local intensity maximum of LED package light output that occurs/can be detected within an LED package light output wavelength range that is equal to or greater than 525 nm and less than or equal to 575 nm.

In embodiment(s), a portion of electromagnetic radiation that is output/emitted (e.g., as the LED package output) by the LED package via the non-visible light converting phosphor, e.g., corresponding to a presence of the non-visible light converting phosphor in the encapsulant of the LED package, comprises a local intensity maximum of LED package light output that occurs/can be detected within an LED package light output wavelength range that is equal to or greater than 680 nm.

In embodiment(s), a method, e.g., of manufacturing LED packages and/or lighting systems, comprises: determining a first defined quantity of a visible light converting phosphor that is to be included in an encapsulant to be used to encapsulate an LED chip that has been bonded to an LED package to facilitate generation, via the LED package, of an LED package light output comprising a defined LED package light output color coordinate and a defined LED package light output intensity, in which the visible light converting phosphor emits first electromagnetic radiation in a visible light spectrum; determining a second defined quantity of a non-visible light converting phosphor that is to be included in the encapsulant to be used to encapsulate the LED chip to facilitate the generation of the LED package light output comprising the defined LED package light output color coordinate and the defined LED package light output intensity, in which the non-visible light converting phosphor emits second electromagnetic radiation in a non-visible light spectrum; and encapsulating the LED chip with the encapsulant comprising the first quantity of the visible light converting phosphor and the second quantity of the non-visible light converting phosphor to facilitate the generation of the LED package light output comprising the defined LED package light output color coordinate and the defined LED package light output intensity.

In other embodiment(s), the determining of the first defined quantity of the visible light converting phosphor that is to be included in the encapsulant comprises: determining that the LED chip has generated an LED chip light output comprising a color that is within a defined LED chip light output color range; and determining the first defined quantity of the visible light converting phosphor based on the color of the LED chip light output that has been determined to be within the defined LED chip light output color range.

In yet other embodiment(s), the determining of the first defined quantity of the visible light converting phosphor that is to be included in the encapsulant further comprises: determining, with respect to a weight of the encapsulant comprising the first defined quantity of the visible light converting phosphor and the second defined quantity of the non-visible light converting phosphor, a defined weight percentage of the visible light converting phosphor that is to be included in the encapsulant.

In embodiment(s), the determining of defined weight percentage of the visible light converting phosphor that is to be included in the encapsulant comprises: obtaining respective samples of a group of LED chips comprising the LED chip, in which the respective samples of the group of LED chips comprise respective LED chip light output wavelengths that have been determined to be within a defined LED light output wavelength range; encapsulating, via a test encapsulant, LED chips of the respective samples within respective LED test packages using respective defined amounts of the visible light converting phosphor; determining LED chip light output wavelengths of the respective LED test packages; and based on the determined LED chip light output wavelengths of the respective LED test packages, determining the defined weight percentage of the visible light converting phosphor that is to be included in the encapsulant.

In other embodiment(s), the determining of the second defined quantity of the non-visible light converting phosphor that is to be included in the encapsulant comprises: determining that the LED chip has generated an LED chip light output comprising an intensity that is within a defined LED chip light output intensity range; and determining the second defined quantity of the non-visible light converting phosphor based on the intensity of the LED chip light output that has been determined to be within the defined LED chip light output intensity range.

In yet other embodiment(s), the determining of the second defined quantity of the non-visible light converting phosphor that is to be included in the encapsulant further comprises: determining, with respect to a weight of the encapsulant comprising the first defined quantity of the visible light converting phosphor and the second defined quantity of the non-visible light converting phosphor, a defined weight percentage of the non-visible light converting phosphor that is to be included in the encapsulant.

In embodiment(s), the determining of defined weight percentage of the non-visible light converting phosphor that is to be included in the encapsulant comprises: obtaining respective samples of a group of LED chips comprising the LED chip, in which the respective samples of the group of LED chips comprise respective LED chip light output intensities that have been determined to be within a defined LED light output intensity range; encapsulating, via a test encapsulant, LED chips of the respective samples within respective LED test packages using respective defined amounts of the non-visible light converting phosphor; determining LED chip light output intensities of the respective LED test packages; and based on the determined LED chip light output intensities of the respective LED test packages, determining the defined weight percentage of the non-visible light converting phosphor that is to be included in the encapsulant.

In other embodiment(s), the method further comprises: electrically connecting, via respective lead frames of the LED package, wires to electrical pads of the LED chip, in which the respective lead frames facilitate bonding of the LED package to a printed circuit board.

In yet other embodiment(s), the method further comprises: disposing the LED package in a manufacturing bin comprising binning parameters representing the defined LED package light output color coordinate and the defined LED package light output intensity.

In embodiment(s), a method, e.g., of manufacturing LED packages and/or lighting systems, comprises: obtaining respective samples of a group of LED chips comprising respective LED chip light output intensities that are within a defined LED light output intensity range and respective LED chip light output wavelengths that are within a defined LED light output wavelength range; in response to varying respective amounts of a non-visible light converting phosphor and respective amounts of a visible light converting phosphor that are included in respective encapsulants that have been used to encapsulate LED chips of the respective samples within respective LED test packages, determining mathematical relationships between the respective amounts of the non-visible light converting phosphor and respective measured LED package light output intensities of first respective LED test packages of the respective LED test packages, and determining correlations between the respective amounts of the visible light converting phosphor and respective measured LED package light output color coordinates of second respective LED test packages of the respective LED test packages.

The method further comprises: based on the determined mathematical relationships and the determined correlations, selecting a first amount of the respective amounts of the non-visible light converting phosphor that has been determined, based on the determined mathematical relationships, to correspond to a measured LED package light output intensity of the respective measured LED package light output intensities that represents a defined target LED package light output intensity of a manufactured LED package, and selecting a second amount of the respective amounts of the visible light converting phosphor that has been determined, based on the determined correlations, to correspond to a measured LED package light output color coordinate of the respective measured LED package light output color coordinates that represents a defined target LED package light output color coordinate of the manufactured LED package.

Further, the method comprises: in response to including the first amount of the non-visible light converting phosphor and the second amount of the visible light converting phosphor in an encapsulant, encapsulating, using the encapsulant, a manufacturing portion of the group of LED chips within respective LED packages to facilitate categorization of the respective LED packages into a manufacturing bin represented by the defined target LED package light output intensity and the defined target LED package light output color coordinate.

In other embodiment(s), a method, e.g., of manufacturing LED packages and/or lighting systems, comprises: obtaining a first portion of LED chips from a group of LED chips comprising respective LED chip light output intensities that are within a defined LED light output intensity range and respective LED chip light output wavelengths that are within a defined LED light output wavelength range; and based on first respective light output intensities and respective light output wavelengths that have been measured from first respective LED packages comprising the first portion of LED chips that have been encapsulated within the first respective LED packages using first respective amounts of a non-visible light converting phosphor, determining mathematical relationships between the first respective amounts of the non-visible light converting phosphor, the first respective light output intensities, and the respective light output wavelengths.

The method further comprises: obtaining a second portion of LED chips from the group of LED chips; and based on second respective light output intensities and respective light output color coordinates that have been measured from second respective LED packages comprising the second portion of LED chips that have been encapsulated within the second respective LED packages using second respective amounts of a visible light converting phosphor and a selected amount of the non-visible light converting phosphor that has been selected, using the mathematical relationships, to correspond to a defined light output intensity, correlating the second respective amounts of the visible light converting phosphor to the respective light output color coordinates.

Further, the method comprises: obtaining a third portion of LED chips from the group of LED chips; and based on the mathematical relationships and the correlating, encapsulating, within third respective LED packages, the third portion of LED chips with a first amount of the non-visible light converting phosphor that has been determined to correspond to a defined target LED package light output intensity of a manufactured LED package and a second amount of the visible light converting phosphor that has been determined to correspond to a defined target LED package light output color coordinate of the manufactured LED package to facilitate classification of the third respective LED packages into a manufacturing bin represented by the defined target LED package light output intensity and the defined/target LED package light output color coordinate.

In yet other embodiment(s), a method, e.g., of manufacturing LED packages and/or lighting systems, comprises: obtaining an LED chip from a group of LED chips comprising respective light output intensities that are within a defined intensity range of LED chip light output intensities and respective light output wavelengths that are within a defined range of LED chip light output wavelengths; and mounting the LED chip on an LED package and electrically connecting, via wires, the LED chip to respective lead frames of the LED package.

Further, the method comprises: based on a light output intensity of the respective light output intensities corresponding to the LED chip and a light output wavelength of the respective light output wavelengths corresponding to the LED chip, encapsulating, within the LED package, the LED chip with a phosphor material comprising a defined visible light converting phosphor amount of a visible light converting phosphor and a defined non-visible light converting phosphor amount of a non-visible light converting phosphor to facilitate generation, via the LED package, of an LED package light output comprising a defined LED package light output intensity and a defined LED package light output color coordinate, and disposing the LED package in a manufacturing bin comprising binning parameters representing the defined LED package light output intensity and the defined LED package light output color coordinate, in which the visible light converting phosphor emits first electromagnetic radiation in a visible light spectrum, and in which the non-visible light converting phosphor emits second electromagnetic radiation in a non-visible light spectrum.

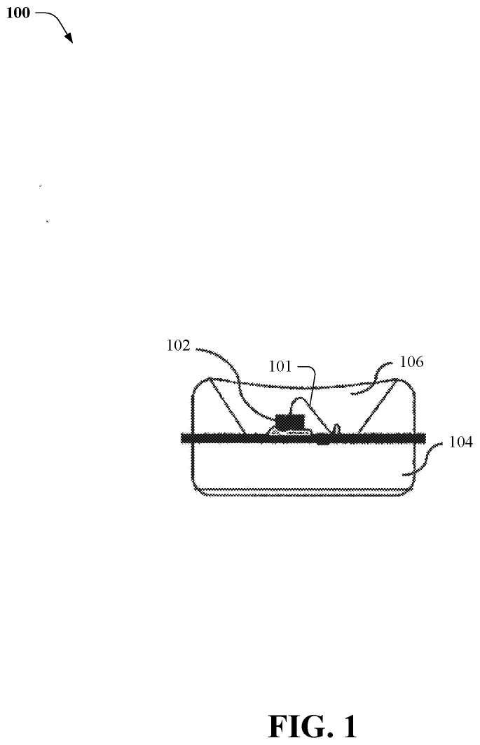

FIG. 1 illustrates a block diagram (100) of a lighting system comprising an LED package (104) that comprises an LED chip (102) that has been mounted on the LED package, and that has been encapsulated with an encapsulant comprising a phosphor material (106) comprising a first converting material (e.g., a first defined quantity of a visible light converting phosphor) and a second converting material (e.g., a second defined quantity of a non-visible light converting phosphor), in accordance with various example embodiment(s). In this regard, a spectral output of the lighting system, e.g., of the LED package, an appearance of the lighting system, and/or a brightness of the lighting system is dependent upon a combination of the first converting material and the second converting material.

The LED package outputs, based on the first defined quantity of the visible light converting phosphor and the second defined quantity of the non-visible light converting phosphor, an LED package light output comprising a defined LED package light output color coordinate and a defined LED package light output intensity, in which the visible light converting phosphor emits first electromagnetic radiation in a visible light spectrum, and in which the non-visible light converting phosphor emits second electromagnetic radiation in a non-visible light spectrum.

In other embodiment(s), the LED package further comprises respective lead frames (not shown) that are electrically connected, via wires (e.g., 101), to electrical pads (not shown) of the LED chip, in which the respective lead frames facilitate bonding of the LED package to a printed circuit board (not shown).

In embodiment(s) (see also below), the LED chip has been determined to generate an LED chip light output comprising a color that is within a defined LED chip light output color range; and the defined LED package light output color coordinate is based on the color of the LED chip light output that is within the defined LED chip light output color range.

In other embodiment(s), the defined LED package light output color coordinate is further based on the first defined quantity of the visible light converting phosphor that has been included in the encapsulant.

In yet other embodiment(s), the first defined quantity of the visible light converting phosphor comprises a defined weight percentage of the visible light converting phosphor with respect to a weight of the encapsulant comprising the first defined quantity of the visible light converting phosphor and the second defined quantity of the non-visible light converting phosphor.

In embodiment(s), the LED chip has been determined to generate an LED chip light output comprising an intensity that is within a defined LED chip light output intensity range; and the defined LED package light output intensity is based on the intensity of the LED chip light output that is within the defined LED chip light output intensity range.

In other embodiment(s), the defined LED package light output intensity is further based on the second defined quantity of the non-visible light converting phosphor that has been included in the encapsulant.

In yet other embodiment(s), the defined LED package light output intensity is negatively proportional to the second defined quantity of the non-visible light converting phosphor that has been included in the encapsulant.

In embodiment(s), the second defined quantity of the non-visible light converting phosphor comprises a defined weight percentage of the non-visible light converting phosphor with respect to a weight of the encapsulant comprising the first defined quantity of the visible light converting phosphor and the second defined quantity of the non-visible light converting phosphor.

In other embodiment(s), the defined LED package light output intensity comprises a defined target light output brightness for white light.

In yet other embodiment(s), the defined LED package light output color coordinate comprises an output color coordinate of a defined color space.

In embodiment(s), the defined LED package light output color coordinate comprises an output color coordinate of a defined color space

In other embodiment(s), the LED chip comprises a blue LED chip or an ultraviolet LED chip.

In yet other embodiment(s), a portion of electromagnetic radiation that is output/emitted (e.g., as an LED package output) by the LED package via the visible light converting phosphor, e.g., corresponding to a presence of the visible light converting phosphor in an encapsulant of the LED package, comprises a local intensity maximum of LED package light output that occurs/can be detected within an LED package light output wavelength range that is equal to or greater than 525 nm and less than or equal to 575 nm.

In embodiment(s), a portion of electromagnetic radiation that is output/emitted (e.g., as the LED package output) by the LED package via the non-visible light converting phosphor, e.g., corresponding to a presence of the non-visible light converting phosphor in the encapsulant of the LED package, comprises a local intensity maximum of LED package light output that occurs/can be detected within an LED package light output wavelength range that is equal to or greater than 680 nm.

Those of ordinary skill in the art of manufacturing LED lighting devices (e.g., LED chips, LED packages, and the like) will appreciate that the phosphor material can contain one or more types of phosphor. As used herein, phosphor refers to any material that converts wavelengths of light irradiating it, is fluorescent, and/or is phosphorescent.

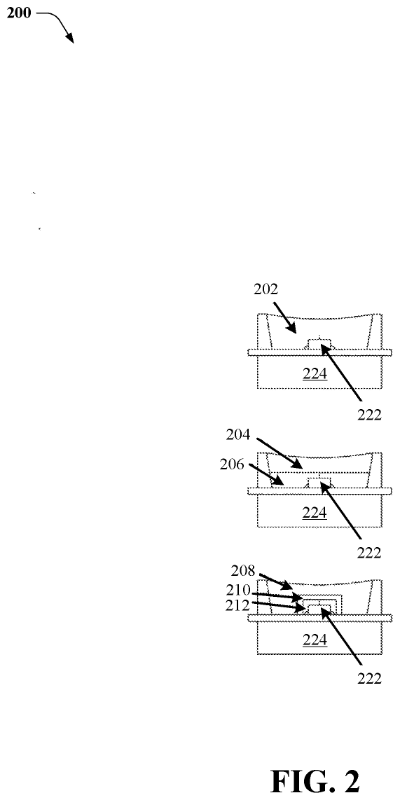

FIG. 2 illustrates a block diagram (200) of respective lighting systems comprising LED packages (224) that comprise respective LED chips (222) that have been encapsulated with respective phosphor materials (202, 204, 206, 208, 210, 212), in accordance with various example embodiment(s). As illustrated by FIG. 2, material 202 comprises a combination of a non-visible light converting phosphor material and a visible light converting phosphor material; material 204 comprises a visible light converting phosphor material; material 206 comprises a non-visible light converting phosphor material; material 208 comprises a clear material; material 210 comprises a visible light converting phosphor material; and material 212 comprises a non-visible light converting phosphor material. In this regard, in various embodiment(s), different types of materials (e.g., 202, 204, 206, 208, 210, 212) can be utilized to encapsulate an LED chip.

In embodiment(s), a first defined quantity/amount of the first converting material, e.g., the visible light converting phosphor, can be varied to derive a desired/specified/defined color/target color, e.g., a defined LED package light output color coordinate, of an LED package light output of an LED package.

In other embodiment(s), a second defined quantity/amount of the second converting material, e.g., the non-visible light converting phosphor, absorbs visible light from an LED chip of the LED package, e.g., converting such light into electromagnetic radiation of a non-visible light range (e.g., non-visible light); therefore, the second defined quantity/amount of the second converting material can be varied to reduce a light output intensity/brightness/lumen output, e.g., to derive and/or control a desired/specified/defined light output intensity, e.g., a defined LED package light output intensity, of the LED package light output of the LED package. As a result, the conversion of light into non-visible light does not significantly influence an output color, e.g., light output wavelength, e.g., the LED package light output color coordinate, of the LED package light output of the LED package; therefore, it is convenient to vary the second quantity/amount of the second converting material to derive and/or control the desired/specified/defined light output intensity/brightness/lumen output, e.g., the defined LED package light output intensity, of the LED package light output of the LED package.

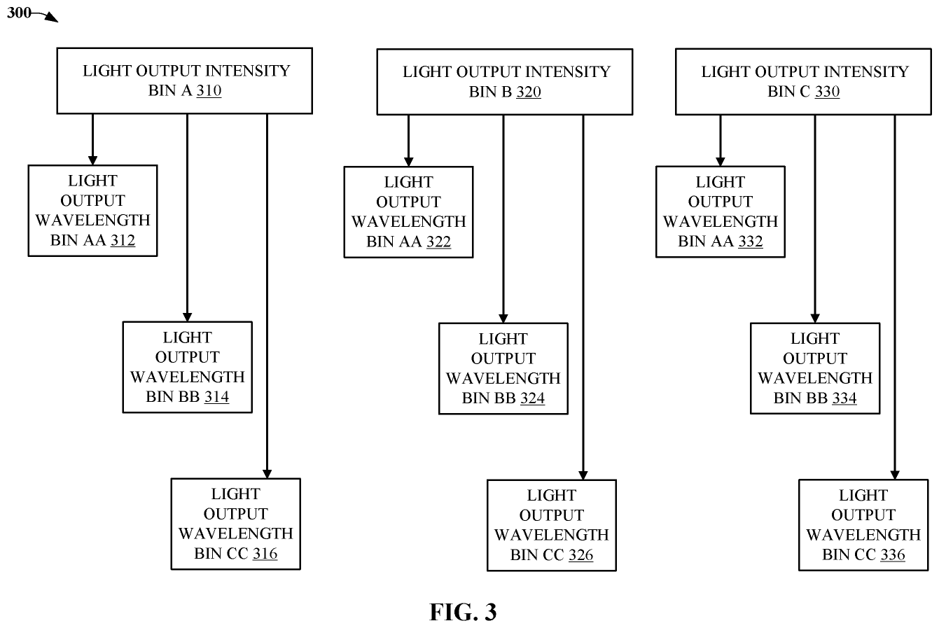

Referring now to FIGS. 3-7, in embodiment(s), a method, e.g., of manufacturing, LED packages includes combining/including respective amounts of visible and non-visible light converting phosphor in respective materials/encapsulants; and encapsulating, using the respective materials/encapsulants, respective LED chips within respective LED packages to limit a number of bins to be created to include the respective LED packages.

FIG. 3. Illustrates a block diagram (300) of bins of LED chips comprising respective light output intensities and respective light output wavelengths-the LED chips supplied by/obtained from an LED chip supplier/manufacturer.

In embodiment(s), the LED chips comprise a blue LED chip or an ultraviolet (UV) LED chip.

As illustrated by FIG. 3, respective portions of the LED chips correspond to LED chip light output intensity bins A (310), B (320), and C (330). In this regard, LED chips of each LED light output intensity bin are further partitioned into (or comprise) LED chip light output wavelength bins, e.g., LED chips of light output intensity bin A are partitioned into (or comprise) light output wavelength bins AA (312), BB (314), and CC (316); LED chips of light output intensity bin B are partitioned into (or comprise) light output wavelength bins AA (322), BB (324), and CC (326); and LED chips of light output intensity bin C are partitioned into (or comprise) light output wavelength bins AA (332), BB (334), and CC (336).

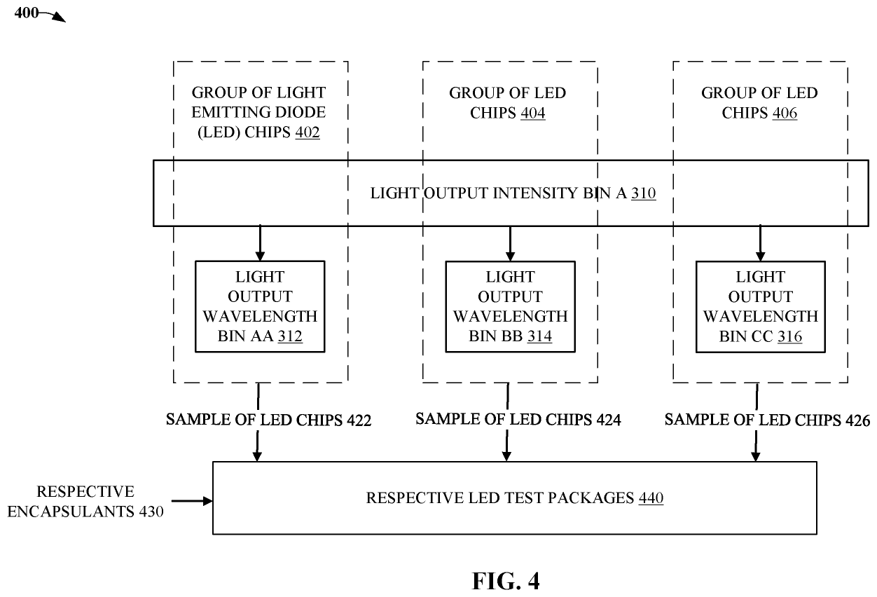

As illustrated by FIG. 4, samples of LED chips (e.g., 422, 424, 426) are obtained from respective groups of LED chips (e.g., 402, 404, 406) corresponding to light output intensity bin A. In this regard, in embodiment(s), the method comprises obtaining respective samples (422) of a group of LED chips (402) comprising respective LED chip light output intensities that are within a defined LED light output intensity range (e.g., corresponding to light output intensity bin A) and respective LED chip light output wavelengths that are within a defined LED light output color/wavelength range (e.g., corresponding to light output wavelength bin AA of light output intensity bin A).

In turn, a first sample of the respective samples, e.g., 240 pieces of LED chips, are mounted on a first portion of LED test packages, e.g., 240 LED test packages, of respective LED test packages 440; and respective LED chips of the first sample are electrically connected, via respective wires, to respective lead frames of the first portion of LED test packages.

Further, the first portion of LED test packages are split into a defined number of groups (e.g., split into 8 groups-each group containing 30 LED test packages), and each group is encapsulated with an encapsulant (e.g., of respective encapsulants 430) that is mixed with a defined weight percentage (%) of non-visible light converting phosphor. For example, each weight percentage of 8 different weight percentages of the non-visible light converting phosphor, e.g., 0%, 2%, 4%, 6%, 8%, 10%, 12%, and 14%, is cast and/or encapsulated into 30 packages of one of the 8 groups.

In this regard, 30 LED chips of one of the 8 groups are encapsulated with 0% weight percentage of the non-visible light converting phosphor; 30 LED chips of another one of the 8 groups are encapsulated with 2% weight percentage of the non-visible light converting phosphor; and so on.

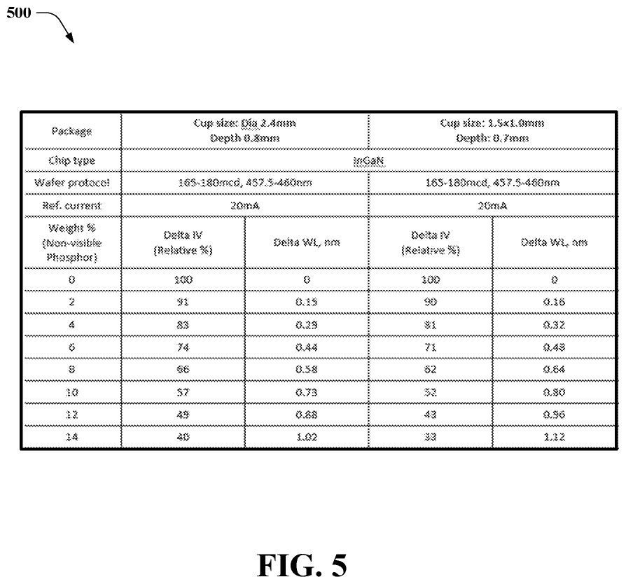

In turn, the first portion of LED test packages are turned on/activated, e.g., individually, and respective LED package light output intensities and respective LED package light output wavelengths of the first portion of LED test packages are measured, e.g., using a spectrometer. Further, as illustrated by FIG. 5, the different weight percentages of non-visible light converting phosphor material-with respect to a weight of an encapsulant comprising the first defined quantity of the visible light converting phosphor and the second defined quantity of the non-visible light converting phosphor-(e.g., “Weight % (Non-visible Phosphor)”) that have been used to encapsulate respective LED chips within respective LED test packages of the first sample, changes in light output intensity of the LED test packages from a defined 100% light output intensity of such packages (e.g., “Delta IV (Relative %)”), and changes in light output wavelength of the LED test packages from a light output wavelength corresponding to the defined 100% LED light output intensity (e.g., “Delta WL, nm”) are included/plotted in a chart/table (500).

In embodiment(s), respective values of the changes in light output intensity and light output wavelength are average values of measurements that have been performed on 30 pieces of LED test packages that have been encapsulated with a particular weight percentage of the non-visible light converting phosphor.

Based on the respective LED package light output intensities and respective LED package light output wavelengths that have been measured, mathematical relationships between the respective amounts of the non-visible light converting phosphor and respective measured LED package light output intensities of the first portion of LED test packages are determined. In this regard, in embodiment(s), the following linear equation can be derived from measurements included/plotted in chart/table 500:
Y=−mx+C, in which
Y=Final/desired/target LED light output intensity/brightness of an LED package (e.g., defined LED package light output intensity),
−mX=LED light output intensity/brightness loss with weight percentage (%) of non-visible phosphor that has been included in an encapsulant of the LED package, and
C=Initial LED light output intensity/brightness of the LED package.

A second sample of the respective samples (e.g., 120 pieces of LED chips) comprising the respective LED chip light output intensities that are within the defined LED light output intensity range corresponding to light output intensity bin A, and comprising the respective LED chip light output wavelengths that are within the defined LED light output color/wavelength range corresponding to light output wavelength bin AA of light output intensity bin A, are mounted on a second portion of LED test packages, e.g., 120 LED test packages, of respective LED test packages 440; and respective LED chips of the second sample are electrically connected, via respective wires, to respective lead frames of the second portion of LED test packages.

Further, the second portion of LED test packages is split into a defined number of groups (e.g., split into 4 groups-each group containing 30 LED test packages). Each group is encapsulated with an encapsulant (e.g., of respective encapsulants 430) that is mixed with one of 4 defined weight percentages (e.g., 2%, 3%, 4%, and 5%) of visible light converting phosphor—with respect to a weight of an encapsulant comprising the first defined quantity of the visible light converting phosphor and the second defined quantity of the non-visible light converting phosphor—and a defined weight percentage of non-visible light converting phosphor (e.g., which has been selected, using the mathematical relationships, to correspond to a defined LED package light output intensity/defined target light output intensity of an LED package light output of an LED package).

In this regard, 30 LED chips of one of the 4 groups are encapsulated with 2% weight percentage of the visible light converting phosphor and the defined weight percentage of non-visible light converting phosphor; 30 LED chips of another one of the 4 groups are encapsulated with 3% weight percentage of the visible light converting phosphor and the defined weight percentage of non-visible light converting phosphor; and so on.

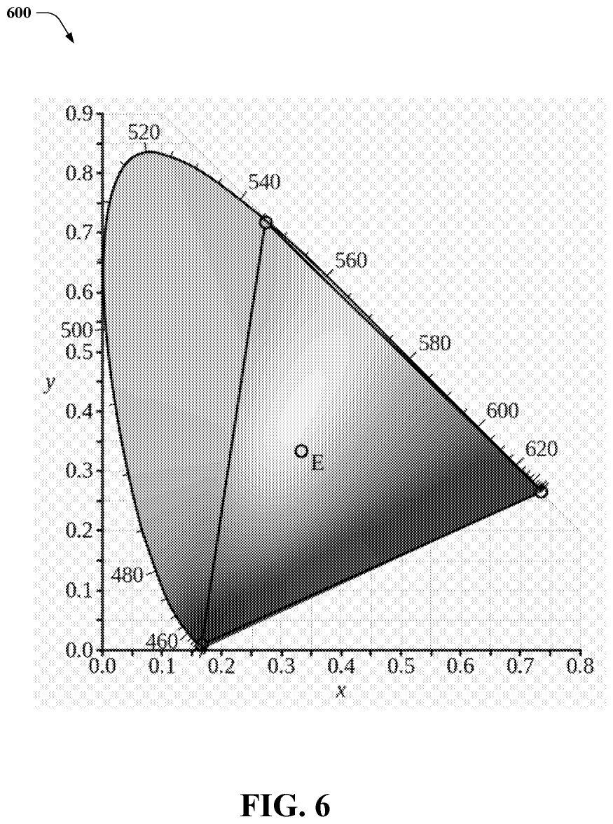

In turn, the second portion of LED test packages are turned on/activated, e.g., individually. Further, respective light output intensities (e.g., corresponding to white light) and respective light output color coordinates (e.g., corresponding to a CIE color space chromaticity diagram illustrated in FIG. 6) are measured from the second portion of LED test packages; and the defined weight percentages (e.g., 2%, 3%, 4%, and 5%) of visible light converting phosphor are correlated with the measured respective light output color coordinates and the respective light output intensities.

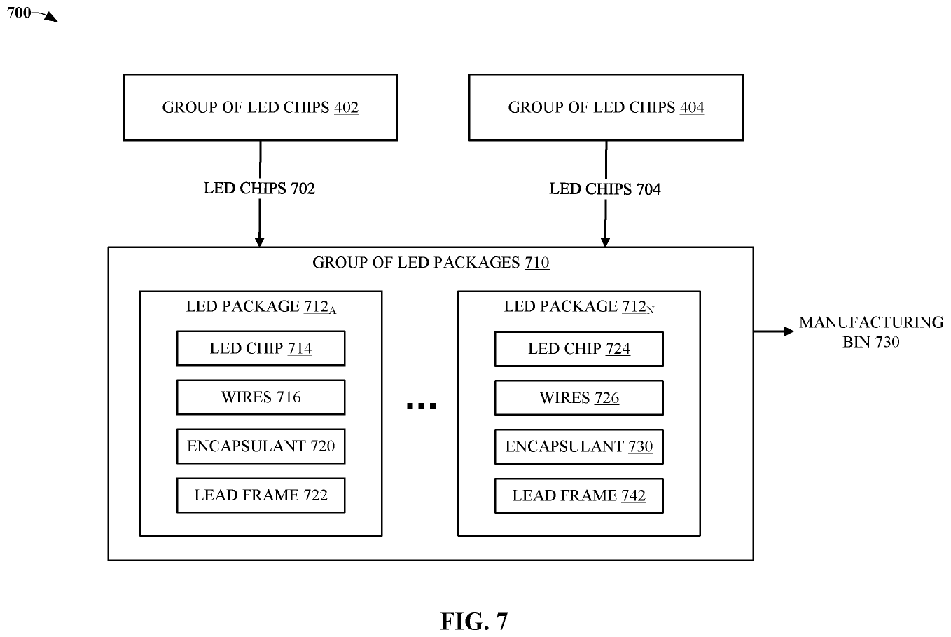

Referring now to FIG. 7, a portion of LED chips (e.g., 702, 704) from the group of LED chips (e.g., 402, 404) comprising the respective LED chip light output intensities that are within the defined LED light output intensity range corresponding to light output intensity bin A, and comprising the respective LED chip light output wavelengths that are within the defined LED light output color/wavelength range corresponding to light output wavelength bin AA of light output intensity bin A, are obtained for manufacture of LED packages (e.g., comprising LED package 712_{A}, 712_{N}) to be placed/dispersed into a manufacturing bin (e.g., manufacturing bin 730).

For example, a portion of LED chips (e.g., comprising LED chip 714) is mounted on respective LED packages (e.g., comprising LED package 712_{A}) of a group of LED packages 710; and respective wires (e.g., 716) are electrically connected, between electrical pads (not shown) of the portion of the LED chips and respective lead frames (e.g., 722) of the respective LED packages, in which the respective lead frames facilitate bonding of the respective LED package to respective printed circuit boards (not shown).

In turn, based on the mathematical relationships and the correlating described above, the portion of LED chips is encapsulated, within the respective LED packages, using an encapsulant (e.g., encapsulant 720) comprising a first defined quantity/amount of the non-visible light converting phosphor that has been determined to correspond to a defined LED package light output intensity (e.g., a defined target white light output intensity and/or a defined target light output brightness for white light) of a manufactured LED package (e.g., corresponding to manufacturing bin 730), and a second quantity/amount of the visible light converting phosphor that has been determined to correspond to a defined/target LED package light output color coordinate (e.g., of a defined (e.g., CIE-based) color space) of the manufactured LED package (e.g., corresponding to manufacturing bin 730) to facilitate classification of the respective LED packages into the manufacturing bin (730) represented by the defined LED package light output intensity and the defined/target LED package light output color coordinate.

In embodiment(s), another portion of LED chips (704) from a group of LED chips (404) comprising other respective LED chip light output intensities, which are greater than the respective LED chip light output intensities corresponding to group of LED chip 402, are obtained for manufacture of LED packages (e.g., comprising LED package 712_{N}) to be placed/dispersed into the manufacturing bin (e.g., manufacturing bin 730).

In this regard, the portion of LED chips 704 (e.g., comprising LED chip 724) is mounted on respective LED packages (e.g., comprising LED package 712_{N}) of the group of LED packages 710; and respective wires (e.g., comprising wires 726) are electrically connected to respective lead frames (e.g., lead frames 742) of the respective LED packages.

In turn, based on the mathematical relationships and the correlating described above, the portion of LED chips 704 is encapsulated, within the respective LED packages, using an encapsulant (e.g., encapsulant 730) comprising a revised amount of the non-visible light converting phosphor that is greater than the first amount of the non-visible light converting phosphor of encapsulant 720—the revised amount being determined to correspond to the defined LED package light output intensity (e.g., the defined target white light output intensity and/or the defined target light output brightness for white light) corresponding to manufacturing bin 730.

In other embodiment(s), another portion of LED chips from a group of LED chips (404) comprising other respective LED chip light output intensities, which are less than the respective LED chip light output intensities corresponding to group of LED chip 402, are obtained for manufacture of LED packages to be placed/dispersed into the manufacturing bin (e.g., manufacturing bin 730).

In this regard, the portion of LED chips is mounted on respective LED packages of the group of LED packages 710; and respective wires are electrically connected to respective lead frames of the respective LED packages.

In turn, based on the mathematical relationships and the correlating described above, the portion of LED chips is encapsulated, within the respective LED packages, using an encapsulant comprising a revised amount of the non-visible light converting phosphor that is less than the first amount of the non-visible light converting phosphor of encapsulant 720 the revised amount being determined to correspond to the defined LED package light output intensity (e.g., the defined target white light output intensity and/or the defined target light output brightness for white light) corresponding to manufacturing bin 730.

In yet other embodiment(s), another portion of LED chips from a group of LED chips (404) comprising other respective LED chip light output intensities, which are less than the respective LED chip light output intensities corresponding to group of LED chip 402, are obtained for manufacture of LED packages to be placed/dispersed into the manufacturing bin (e.g., manufacturing bin 730).

In this regard, the portion of LED chips is mounted on respective LED packages of the group of LED packages 710; and respective wires are electrically connected to respective lead frames of the respective LED packages.

In turn, based on the mathematical relationships and the correlating described above, the portion of LED chips is encapsulated, within the respective LED packages, using an encapsulant that does not include the non-visible light converting phosphor to facilitate classification/placement of the respective LED packages into manufacturing bin 730.

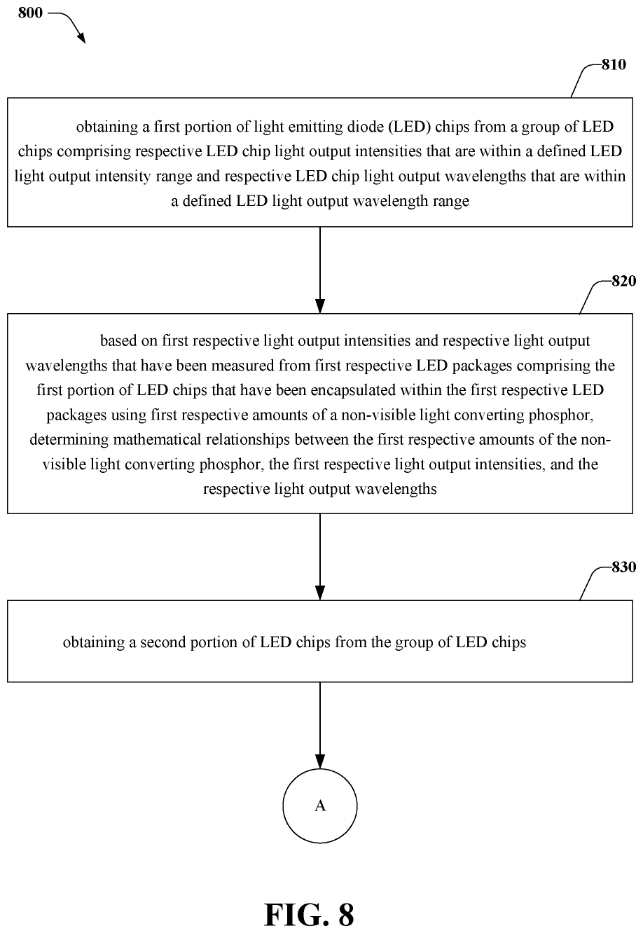

FIGS. 8-11 illustrate methodologies in accordance with the disclosed subject matter. For simplicity of explanation, the methodologies are depicted and described as a series of acts. It is to be understood and appreciated that various embodiments disclosed herein are not limited by the acts illustrated and/or by the order of acts. For example, acts can occur in various orders and/or concurrently, and with other acts not presented or described herein. Furthermore, not all illustrated acts may be required to implement the methodologies in accordance with the disclosed subject matter. In addition, those skilled in the art will understand and appreciate that the methodologies could alternatively be represented as a series of interrelated states via a state diagram or events.

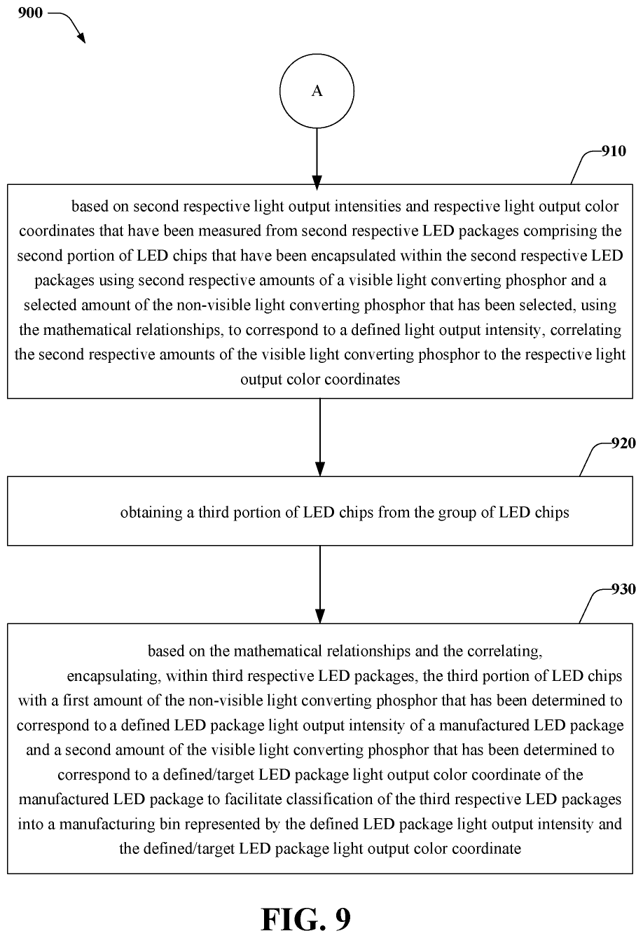

FIGS. 8-9 illustrate flow charts (800, 900) of a method associated with process(es) for manufacturing LED packages comprising respective LED chips that have been encapsulated with respective phosphor materials comprising visible and non-visible light converting phosphor, in accordance with various example embodiment(s).

At 810, a first portion of LED chips is obtained from a group of LED chips comprising respective LED chip light output intensities that are within a defined LED light output intensity range and respective LED chip light output wavelengths that are within a defined LED light output color/wavelength range.

At 820, based on first respective light output intensities and respective light output wavelengths that have been measured from first respective LED packages comprising the first portion of LED chips that have been encapsulated within the first respective LED packages using first respective amounts of a non-visible light converting phosphor, mathematical relationships between the first respective amounts of the non-visible light converting phosphor, the first respective light output intensities, and the respective light output wavelengths are determined.

At 830, a second portion of LED chips are obtained from the group of LED chips. At 910, based on second respective light output intensities and respective light output color coordinates that have been measured from second respective LED packages comprising the second portion of LED chips that have been encapsulated within the second respective LED packages using second respective amounts of a visible light converting phosphor and a selected amount of the non-visible light converting phosphor that has been selected, using the mathematical relationships, to correspond to a defined light output intensity, the second respective amounts of the visible light converting phosphor are correlated to the respective light output color coordinates.

At 920, a third portion of LED chips are obtained from the group of LED chips. At 930, based on the mathematical relationships and the correlation of the second respective amounts of the visible light converting phosphor to the respective light output color coordinates, the third portion of LED chips are encapsulated, within third respective LED packages, with a first amount of the non-visible light converting phosphor that has been determined to correspond to a defined LED package light output intensity of a manufactured LED package and a second amount of the visible light converting phosphor that has been determined to correspond to a defined/target LED package light output color coordinate of the manufactured LED package to facilitate classification of the third respective LED packages into a manufacturing bin represented by the defined LED package light output intensity and the defined/target LED package light output color coordinate.

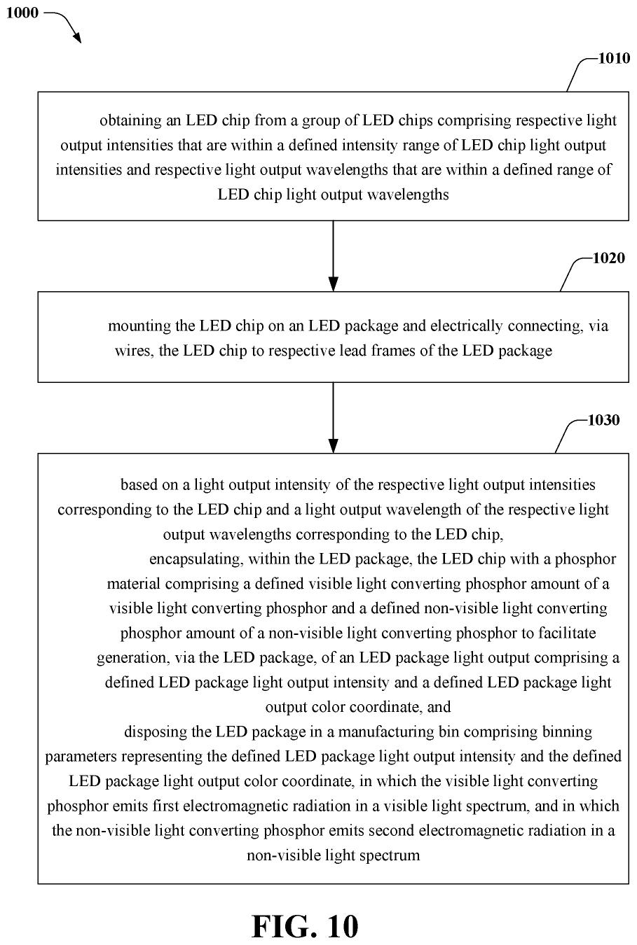

FIG. 10 illustrates a flow chart (1000) of a method associated with process(es) for manufacturing LED packages comprising respective LED chips that have been encapsulated with respective phosphor materials comprising visible and non-visible light converting phosphor, in accordance with various example embodiment(s).

At 1010, an LED chip is obtained from a group of LED chips comprising respective light output intensities that are within a defined intensity range of LED chip light output intensities, e.g., within a defined LED chip light output intensity range, and respective light output wavelengths that are within a defined range of LED chip light output wavelengths, e.g. within a defined LED chip light output color range.

At 1020, the LED chip is mounted on an LED package and electrically connected, via wires, to respective lead frames of the LED package.

At 1030, based on a light output intensity of the respective light output intensities corresponding to the LED chip and a light output wavelength of the respective light output wavelengths corresponding to the LED chip, the LED chip is encapsulated, within the LED package, with a phosphor material comprising a defined visible light converting phosphor amount of a visible light converting phosphor and a defined non-visible light converting phosphor amount of a non-visible light converting phosphor to facilitate generation, via the LED package, of an LED package light output comprising a defined LED package light output intensity and a defined LED package light output color coordinate.

Further, the LED package is disposed in a manufacturing bin comprising binning parameters representing the defined LED package light output intensity and the defined LED package light output color coordinate, in which the visible light converting phosphor emits first electromagnetic radiation in a visible light spectrum, and in which the non-visible light converting phosphor emits second electromagnetic radiation in a non-visible light spectrum.

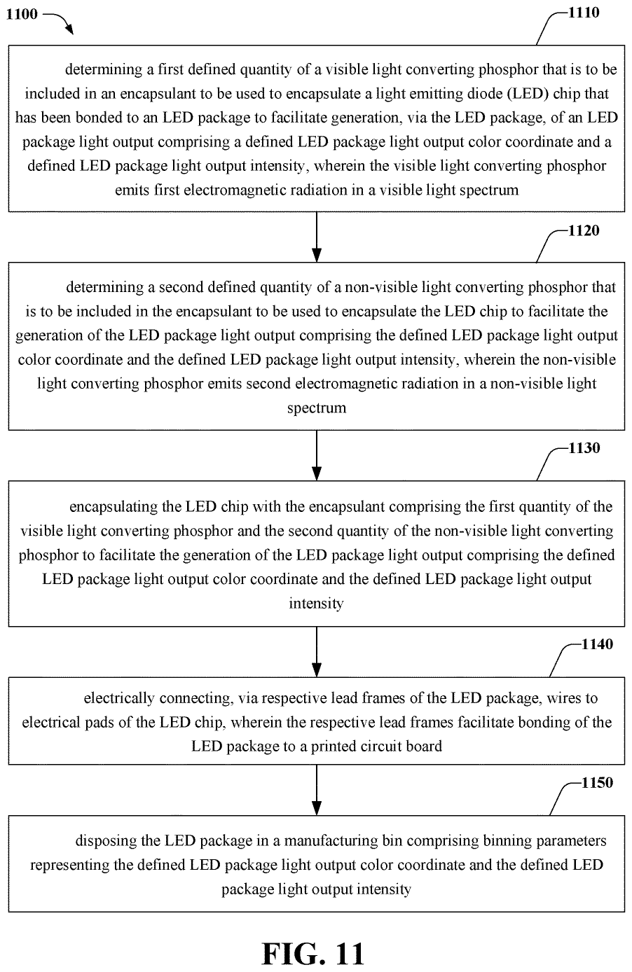

FIG. 11 illustrates a flow chart (1100) of another method associated with process(es) for manufacturing LED packages comprising respective LED chips that have been encapsulated with respective phosphor materials comprising visible and non-visible light converting phosphor, in accordance with various example embodiment(s).

At 1110, a first defined quantity of a visible light converting phosphor that is to be included in an encapsulant to be used to encapsulate an LED chip that has been bonded to an LED package is determined-to facilitate generation, via the LED package, of an LED package light output comprising a defined LED package light output color coordinate and a defined LED package light output intensity, in which the visible light converting phosphor emits first electromagnetic radiation in a visible light spectrum.

At 1120, a second defined quantity of a non-visible light converting phosphor that is to be included in the encapsulant to be used to encapsulate the LED chip is determined—to facilitate the generation of the LED package light output comprising the defined LED package light output color coordinate and the defined LED package light output intensity, in which the non-visible light converting phosphor emits second electromagnetic radiation in a non-visible light spectrum.

At 1130, the LED chip is encapsulated with the encapsulant comprising the first quantity of the visible light converting phosphor and the second quantity of the non-visible light converting phosphor to facilitate the generation of the LED package light output comprising the defined LED package light output color coordinate and the defined LED package light output intensity.

At 1140, wires are electrically connected, via respective lead frames of the LED package, to electrical pads of the LED chip, in which the respective lead frames facilitate bonding of the LED package to a printed circuit board.

At 1150, the LED package is disposed in a manufacturing bin comprising binning parameters representing the defined LED package light output color coordinate and the defined LED package light output intensity.

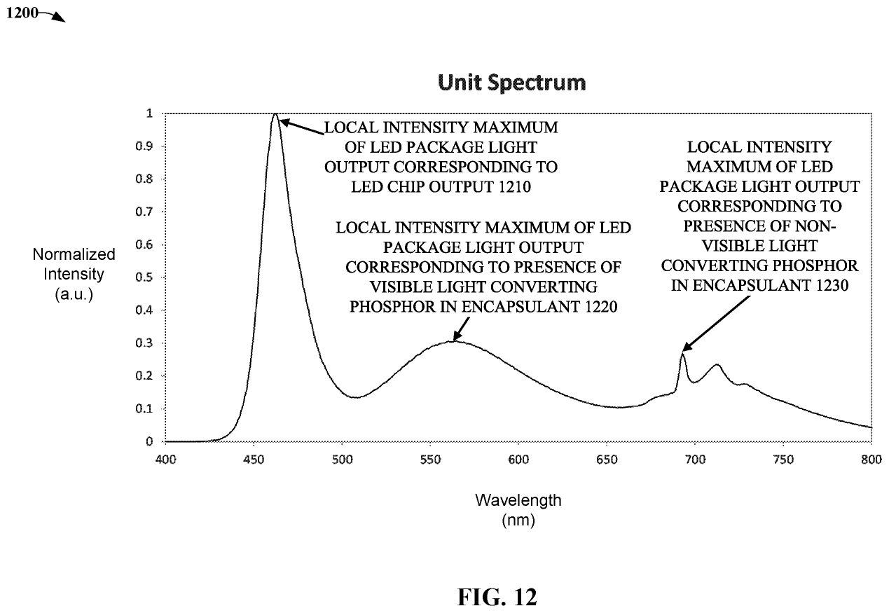

FIG. 12 illustrates a plot (1200) of normalized intensity per light output wavelength of electromagnetic radiation (e.g., comprising visible light, visually detectable electromagnetic radiation) that has been emitted/output by an LED package (e.g., an LED package light output), in which the LED package comprises an LED chip (e.g., blue LED chip) that has been encapsulated with an encapsulant comprising a phosphor material comprising visible light converting phosphor and non-visible light converting phosphor, in accordance with various example embodiment(s).

In embodiment(s), a local intensity maximum of the LED package light output that corresponds to an output of the LED chip (e.g., an LED chip output) (1210) occurs within an LED package light output wavelength range that is equal to or greater than 455 nm and less than or equal to 470 nm.

Further, a local intensity maximum of the LED package light output that corresponds to a presence of the visible light converting phosphor in the encapsulant (1220) occurs within an LED package light output wavelength range that is equal to or greater than 525 nm and less than or equal to 575 nm.

Additionally, a local intensity maximum of the LED package light output that corresponds to a presence of the non-visible light converting phosphor in the encapsulant (1230) occurs within an LED package light output wavelength range that is equal to or greater than 680 nm.

In embodiment(s), light detection equipment, e.g., a spectrometer, can be used to detect that non-visible light converting phosphor has been included in an encapsulant that has been used to encapsulate an LED chip of an LED package. For example, responsive to a determination via the spectrometer that the LED package light output includes a local intensity maximum at a wavelength that is equal to or greater than a 680 nm, it can be determined that the non-visible light converting phosphor is present within the encapsulant of the LED package.

In other embodiment(s), the light detection equipment can be used to additionally detect that visible light converting phosphor has been included in the encapsulant.

For example, responsive to a determination via the spectrometer that the LED package light output includes a local intensity maximum at a wavelength that is equal to or greater than 525 nm and less than or equal to 575 nm, it can be determined that the visible light converting phosphor is present within the encapsulant of the LED package.

Reference throughout this specification to “one embodiment,” “an embodiment,” “another embodiment”, “yet another embodiment”, “embodiment(s)”, “other “embodiment(s)”, and “yet other embodiment(s)” means that a particular feature, structure, or characteristic described in connection with the embodiment is included in at least one embodiment. Thus, the appearances of the phrase “in one embodiment,” “in an embodiment,” “in another embodiment”, “in yet another embodiment”, “in embodiment(s)”, “in other embodiment(s)”, and “in yet other embodiment(s)” in various places throughout this specification are not necessarily all referring to the same embodiment. Furthermore, the particular features, structures, or characteristics may be combined in any suitable manner in one or more embodiments.

Furthermore, to the extent that the terms “includes,” “has,” “contains,” and other similar words are used in either the detailed description or the appended claims, such terms are intended to be inclusive—in a manner similar to the term “comprising” as an open transition word—without precluding any additional or other elements. Moreover, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Furthermore, the word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art having the benefit of the instant disclosure.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

What is claimed is:

1. A light emitting diode (LED) package, comprising:
an LED chip that has been encapsulated with an encapsulant, wherein the encapsulant comprises a first defined quantity of a visible light converting phosphor and a second defined quantity of a non-visible light converting phosphor, wherein the LED package outputs, based on the first defined quantity of the visible light converting phosphor and the second defined quantity of the non-visible light converting phosphor, an LED package light output comprising a defined LED package light output color coordinate and a defined LED package light output intensity, wherein the visible light converting phosphor emits first electromagnetic radiation in a visible light spectrum, and wherein the non-visible light converting phosphor emits second electromagnetic radiation in a non-visible light spectrum; and
respective lead frames that are electrically connected, via wires, to electrical pads of the LED chip, wherein the respective lead frames facilitate bonding of the LED package to a printed circuit board.

2. The LED package of claim 1, wherein the LED chip has been determined to generate an LED chip light output comprising a color that is within a defined LED chip light output color range, and wherein the defined LED package light output color coordinate is based on the color of the LED chip light output that is within the defined LED chip light output color range.

3. The LED package of claim 2, wherein the defined LED package light output color coordinate is further based on the first defined quantity of the visible light converting phosphor that has been included in the encapsulant.

4. The LED package of claim 1, wherein the first defined quantity of the visible light converting phosphor comprises a defined weight percentage of the visible light converting phosphor with respect to a weight of the encapsulant comprising the first defined quantity of the visible light converting phosphor and the second defined quantity of the non-visible light converting phosphor.

5. The LED package of claim 1, wherein the LED chip has been determined to generate an LED chip light output comprising an intensity that is within a defined LED chip light output intensity range, and wherein the defined LED package light output intensity is based on the intensity of the LED chip light output that is within the defined LED chip light output intensity range.

6. The LED package of claim 5, wherein the defined LED package light output intensity is further based on the second defined quantity of the non-visible light converting phosphor that has been included in the encapsulant.

7. The LED package of claim 6, wherein the defined LED package light output intensity is negatively proportional to the second defined quantity of the non-visible light converting phosphor that has been included in the encapsulant.

8. The LED package of claim 1, wherein the second defined quantity of the non-visible light converting phosphor comprises a defined weight percentage of the non-visible light converting phosphor with respect to a weight of the encapsulant comprising the first defined quantity of the visible light converting phosphor and the second defined quantity of the non-visible light converting phosphor.

9. The LED package of claim 1, wherein the defined LED package light output intensity comprises a defined target light output brightness for white light.

10. The LED package of claim 1, wherein the defined LED package light output color coordinate comprises an output color coordinate of a defined color space.

11. The LED package of claim 1, wherein the LED chip comprises a blue LED chip or an ultraviolet LED chip.

12. A method, comprising:
determining a first defined quantity of a visible light converting phosphor that is to be included in an encapsulant to be used to encapsulate a light emitting diode (LED) chip that has been bonded to an LED package to facilitate generation, via the LED package, of an LED package light output comprising a defined LED package light output color coordinate and a defined LED package light output intensity, wherein the visible light converting phosphor emits first electromagnetic radiation in a visible light spectrum;
determining a second defined quantity of a non-visible light converting phosphor that is to be included in the encapsulant to be used to encapsulate the LED chip to facilitate the generation of the LED package light output comprising the defined LED package light output color coordinate and the defined LED package light output intensity, wherein the non-visible light converting phosphor emits second electromagnetic radiation in a non-visible light spectrum; and
encapsulating the LED chip with the encapsulant comprising the first quantity of the visible light converting phosphor and the second quantity of the non-visible light converting phosphor to facilitate the generation of the LED package light output comprising the defined LED package light output color coordinate and the defined LED package light output intensity.

13. The method of claim 12, wherein the determining of the first defined quantity of the visible light converting phosphor that is to be included in the encapsulant comprises:
determining that the LED chip has generated an LED chip light output comprising a color that is within a defined LED chip light output color range; and
determining the first defined quantity of the visible light converting phosphor based on the color of the LED chip light output that has been determined to be within the defined LED chip light output color range.

14. The method of claim 13, wherein the determining of the first defined quantity of the visible light converting phosphor that is to be included in the encapsulant further comprises:
determining, with respect to a weight of the encapsulant comprising the first defined quantity of the visible light converting phosphor and the second defined quantity of the non-visible light converting phosphor, a defined weight percentage of the visible light converting phosphor that is to be included in the encapsulant.

15. The method of claim 14, wherein the determining of defined weight percentage of the visible light converting phosphor that is to be included in the encapsulant comprises:
obtaining respective samples of a group of LED chips comprising the LED chip, wherein the respective samples of the group of LED chips comprise respective LED chip light output wavelengths that have been determined to be within a defined LED light output wavelength range;
encapsulating, via a test encapsulant, LED chips of the respective samples within respective LED test packages using respective defined amounts of the visible light converting phosphor;
determining LED chip light output wavelengths of the respective LED test packages; and
based on the determined LED chip light output wavelengths of the respective LED test packages, determining the defined weight percentage of the visible light converting phosphor that is to be included in the encapsulant.

16. The method of claim 12, wherein the determining of the second defined quantity of the non-visible light converting phosphor that is to be included in the encapsulant comprises:
determining that the LED chip has generated an LED chip light output comprising an intensity that is within a defined LED chip light output intensity range; and
determining the second defined quantity of the non-visible light converting phosphor based on the intensity of the LED chip light output that has been determined to be within the defined LED chip light output intensity range.

17. The method of claim 16, wherein the determining of the second defined quantity of the non-visible light converting phosphor that is to be included in the encapsulant further comprises:
determining, with respect to a weight of the encapsulant comprising the first defined quantity of the visible light converting phosphor and the second defined quantity of the non-visible light converting phosphor, a defined weight percentage of the non-visible light converting phosphor that is to be included in the encapsulant.

18. The method of claim 17, wherein the determining of defined weight percentage of the non-visible light converting phosphor that is to be included in the encapsulant comprises:
obtaining respective samples of a group of LED chips comprising the LED chip, wherein the respective samples of the group of LED chips comprise respective LED chip light output intensities that have been determined to be within a defined LED light output intensity range;
encapsulating, via a test encapsulant, LED chips of the respective samples within respective LED test packages using respective defined amounts of the non-visible light converting phosphor;
determining LED chip light output intensities of the respective LED test packages; and
based on the determined LED chip light output intensities of the respective LED test packages, determining the defined weight percentage of the non-visible light converting phosphor that is to be included in the encapsulant.

19. The method of claim 12, further comprising:
electrically connecting, via respective lead frames of the LED package, wires to electrical pads of the LED chip, wherein the respective lead frames facilitate bonding of the LED package to a printed circuit board.

20. The method of claim 12, further comprising:
disposing the LED package in a manufacturing bin comprising binning parameters representing the defined LED package light output color coordinate and the defined LED package light output intensity.
